(19) United States
(12) Patent Application Publication
(10) Pub. No.: US 2018/0136509 A1
(43) Pub. Date: May 17, 2018

(54) METHOD OF DIVIDING DISPLAY MEMBER AND METHOD OF MANUFACTURING LIQUID CRYSTAL DISPLAY APPARATUS

(71) Applicant: SAKAI DISPLAY PRODUCTS CORPORATION, OSAKA (JP)

(72) Inventor: MITSUHIRO SHIGETA, OSAKA (JP)

(21) Appl. No.: 15/854,205

(22) Filed: Dec. 26, 2017

Related U.S. Application Data
(63) Continuation-in-part of application No. PCT/JP2015/069334, filed on Jul. 3, 2015.

(51) Int. Cl. G02F 1/1333; H01L 27/12; G02F 1/13; G02F 1/1339

(52) U.S. Cl. CPC G02F 1/133351; G02F 1/1339; G02F 1/1303; H01L 27/1262

(57) ABSTRACT

Provided are a method of dividing a display member that enables to excellently and efficiently cut the film and the adhesive without generating a residue and to scribe a substrate, so that the substrate can be divided easily and excellently, and a method for manufacturing a liquid crystal display apparatus including dividing the substrate using the method of dividing the display member. A TFT substrate (2) and a CF substrate (4) of a display member (1) are bonded with a liquid crystal layer (3) between using a sealing material. A polarization film (6) is adhered to a surface of the CF substrate, the surface opposite to the liquid crystal layer, using a curing type adhesive (5). Using an ultrasonic cutting roller (20) which can be vibrated by ultrasonic waves, the polarization film and the curing type adhesive are cut, the CF substrate is scribed, and the CF substrate is divided.

### CROSS-REFERENCE TO RELATED APPLICATION

This is a continuation-in-part of PCT international application No. PCT/JP2015/069334 filed on Jul. 3, 2015, incorporated herein by reference.

### BACKGROUND OF THE INVENTION

The present disclosure relates to a method of dividing a display member provided on a television receiver, a personal computer and the like, and a method of manufacturing a liquid crystal display apparatus.

Within the field of display apparatus, a liquid crystal display apparatus can have characteristics of thin profile and low power consumption. Particularly, a liquid crystal display apparatus provided with a thin film transistor (TFT) substrate having a switching element such as TFT for each pixel has a high contrast ratio and excellent response characteristics and exhibits high performance, and therefore, it is suitably used for, for example, a television receiver, a personal computer.

FIG. 11 shows a schematic cross-sectional view of a display panel of a conventional liquid crystal display apparatus.

The display panel includes a TFT (active matrix) substrate 2, a liquid crystal layer 3, a CF substrate (color filter substrate) 4 and a polarizing film 6.

The TFT substrate 2 and the CF substrate 4 are bonded with a liquid crystal layer 3 between using a sealing material. The TFT substrate 2 is formed, for example, by providing a pixel electrode (not shown) on an insulating substrate made of glass, and the CF substrate 4 is formed, for example, by providing a common electrode (not shown) on an insulating substrate made of glass. The polarizing film 6 is adhered to a surface of the CF substrate 4, which is the surface opposite to the liquid crystal layer 3, using a curing type adhesive 5. The polarizing film 6 is formed from an optical film such as PVA film having each of both surfaces covered with a protective film. Another polarizing film (not shown) is provided on a surface of the TFT substrate 2, which is the surface opposite to the liquid crystal layer 3.

When a defective part is found in a display region of the display panel, for example, on the CF substrate 4, the defective part of the CF substrate 4 is cut off (half-cut) and removed so as to reproduce a display panel by using a remaining part.

When the polarizing film 6 is adhered onto the CF substrate 4 including the insulating substrate made of glass using the curing type adhesive 5 and then the CF substrate 4 is divided while the polarizing film 6 is cut off, the following problems occur.

The polarizing film 6 has a flexibility while the CF substrate 4 has a rigidity, and the polarizing film 6 and the CF substrate 4 are adhered each other by the curing type adhesive 5. Therefore, it is difficult to divide the CF substrate 4 on which the polarizing film 6 is provided.

FIG. 12 shows a schematic cross-sectional view of a display panel of a conventional liquid crystal display apparatus. As shown in FIG. 12, when separating the polarizing film 6, a residue 51 is left from the curing type adhesive 5 since the adhesivity of the curing type adhesive 5 to the substrate is high. When the residue 51 is generated, it becomes difficult to divide the CF substrate 4.

FIG. 13 shows a schematic cross-sectional view of a display panel of a conventional liquid crystal display apparatus. When dividing the CF substrate 4 in a way shown in FIG. 13, a space is generated at the divided part and the space is put in a reduced pressure state, resulting in a generation of air bubbles 3a within the liquid crystal layer 3.

JP H07-049474 A discloses an invention relating to a cutting device for cutting a film of the liquid crystal display panel comprising a laminated base material which holds a liquid crystal material between a pair of the two resin film substrates, in which a display electrode is provided on a first substrate of the pair of the two substrates and an extraction electrode is provided on a second substrate of the pair of the two substrates. In order to expose the extraction electrode by separating and removing the part of the resin film substrate corresponding to the part to be exposed, the cutting device comprises a cutting blade for cutting only one of the resin film substrates, a main body for holding the cutting blade, slide leg portions attached to the main body in parallel with the cutting blades on both sides of the cutting blade, a screw for moving vertically at least one of the slide leg portions, suppressing means for restraining the surface of the film of the liquid crystal display panel and providing the flatness of the cut position, and a guide portion for guiding the movement of the slide leg portions provided on the suppressing means.

No optical film is adhered to the resin film substrate as the laminated base material of JP H07-049474 A. Further, the base material for the substrate is a synthetic resin, not glass. Therefore, if the device described in JP H07-049474 A is used for half-cutting a display member in which an optical film is adhered to a glass substrate, it is difficult to cut the optical film and the glass substrate easily, impossible to prevent the generation of a residue from a curing type adhesive. The above-mentioned problems resulting from dividing a substrate cannot be solved.

### SUMMARY OF THE INVENTION

The present invention has been made in view of such circumstances as mentioned above, and an object of the present invention is to provide a method of dividing a display member, which enables to excellently and efficiently cut a film and an adhesive without generating a residue and to scribe a substrate, so that the substrate can be divided easily and excellently, and a method of manufacturing a liquid crystal display apparatus comprising a step of dividing the substrate by the above-mentioned dividing method.

A method of dividing a display member comprising a pair of substrates bonded together at respective peripheral edges thereof and a film adhered to at least a first surface of the pair of substrates using an adhesive according to one embodiment of the present invention comprises cutting the film and the adhesive using a cutting tool vibrated by ultrasonic waves on the display member, and then scribing the substrate, and dividing the substrate.

In this embodiment, a cutting tool vibrated by ultrasonic waves is used, and thus cutting and scribing can be employed excellently and efficiently to various materials, from a synthetic resin material having a flexibility to a hard material such as glass.

This enables to cut the adhesive without generating a residue and to divide the substrate excellently and efficiently.

In another embodiment of the method of dividing a display member according to the present application, the cutting tool is an ultrasonic cutting roller.

According to the presently illustrated embodiment, the substrate can be scribed while the film and the adhesive is easily and uniformly cut.

In yet another embodiment of the method of dividing a display member according to the present application, a center part in the width direction of an outer circumferential surface of the ultrasonic cutting roller is recessed, and the ultrasonic cutting roller comprises a cutting portion, onto which cutter edges are provided at both ends in the width direction of the outer circumferential surface of the ultrasonic cutting roller.

According to the embodiment of the present application, cut pieces from the material to be cut can be discharged from the recess in the width direction of the outer circumferential surface of the cutting roller.

In yet another embodiment of the method of dividing a display member according to the present application, the adhesive is cut with an ultrasonic cutter blade.

In the presently illustrated embodiment, when a residue is generated upon cutting the adhesive, the residue can be cut out, thereby the substrate can be divided easily.

In yet another embodiment of the method of dividing a display member according to the present application, after scribing the substrate, a sealing compound is applied to a cut part of the film and a cut part of the adhesive, and the substrate is divided.

In the presently illustrated embodiment, the sealing compound can penetrate into cracks generated in the substrate by scribing process utilizing capillary phenomenon, and after dividing the substrate, the sealing compound can penetrate into a space generated between the substrates at the part where the substrate was divided due to the difference between the pressure in the space between the substrates and the atmospheric pressure outside the substrates, thereby preventing an entering of air bubbles into the space between the substrates.

In yet another embodiment of the method of dividing a display member according to the present application, the scribing of the substrate and an application of the sealing compound are performed under a reduced pressure, and the substrate is divided.

According to the embodiment of the present application, the scribing of the substrate is performed under a reduced pressure, preventing an entering of air into the cracks in the substrate and a generation of air bubbles. Further, the sealing compound penetrates into the cracks when dividing the substrate, which is after applying the sealing compound on the divided parts of the substrate under a reduced pressure and then removing and putting the substrate in the atmosphere to be divided. The sealing compound penetrates into the space generated between the substrates at the part where the substrate was divided utilizing capillary phenomenon and the atmospheric pressure after the completion of the dividing, thereby preventing a generation of air bubbles while the substrate is divided.

In yet another embodiment of the method of dividing a display member according to the present application, the film is an optical film.

Since the optical film has a flexibility, cutting is difficult. However, in the presently illustrated embodiment, the cutting is performed using a cutting tool vibrated by ultrasonic waves, and therefore, the cutting can be performed satisfactorily.

In yet another embodiment of a method of manufacturing a liquid crystal display apparatus according to the present application, the method comprises manufacturing a display member by providing a liquid crystal layer between two substrates, dividing the one substrate by any one of the methods for dividing a display member described above for the method of manufacturing the liquid crystal display apparatus, removing the one of the divided parts of the substrate and reproducing a part of the substrate corresponding to a removed part.

In the presently illustrated embodiment, when a defective part is found in one of the substrates, the substrate can be half-cut excellently to manufacture a reproduced article of the liquid crystal display apparatus having high-quality display region.

According to an exemplary embodiment of the method of dividing a display member of the present invention, the method comprises cutting the film and the adhesive using a cutting tool vibrated by ultrasonic waves and dividing the substrate by performing scribing process to the substrate, enabling to excellently and efficiently cut the film and the adhesive without generating a residue and to scribe a substrate, so that the substrate can be divided easily and excellently.

According to an exemplary embodiment of the method of manufacturing a liquid crystal display apparatus of the present invention, the method comprises dividing the one of the substrates by the method for dividing the display member according to the present invention, removing the one of the divided parts of the substrate, and reproducing a part of the substrate corresponding to the removed part, which enables to perform an excellent half-cut on the substrate when a defective part is found in one of the substrates and to manufacture a reproduced article of the liquid crystal display apparatus having high-quality display region.

### BRIEF DESCRIPTION OF THE DRAWINGS

FIG. 1 shows an external perspective view of a liquid crystal display apparatus for a television receiver according to Embodiment 1.

FIG. 2 shows a schematic plan view of a display panel of a liquid crystal display apparatus.

FIG. 3 shows a schematic cross-sectional view of a display panel when viewing the display panel in FIG. 2 from a right side.

FIG. 4 shows a schematic cross-sectional view of an ultrasonic cutting roller.

FIG. 5 shows a schematic cross-sectional view of an ultrasonic cutting roller.

FIG. 6 shows a schematic cross-sectional view of the CF substrate during the scribing process.

FIG. 7 shows a schematic cross-sectional view of the CF substrate to which a sealing compound is applied at the cut parts of the polarizing film and the adhesive after subjecting the CF substrate to scribing process.

FIG. 8 shows a schematic cross-sectional view of the CF substrate after being divided and a defective part was removed.

FIG. 9 shows a schematic plan view of a reproduced display panel.

FIG. 10 shows a schematic cross-sectional view of an ultrasonic cutter blade.

FIG. 11 shows a schematic cross-sectional view of a display panel of a conventional liquid crystal display apparatus.

FIG. 12 shows a schematic cross-sectional view of a display panel of a conventional liquid crystal display apparatus.

FIG. 13 shows a schematic cross-sectional view of a display panel of a conventional liquid crystal display apparatus.

### DETAILED DESCRIPTION

The invention will be further described below in terms of several embodiments and particularly in terms of drawings showing some embodiments.

### Embodiment 1

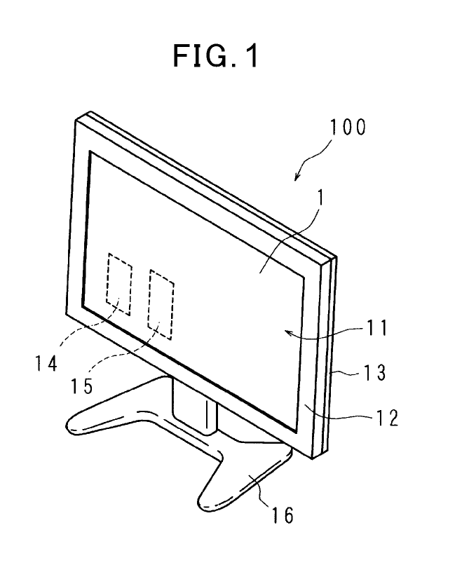

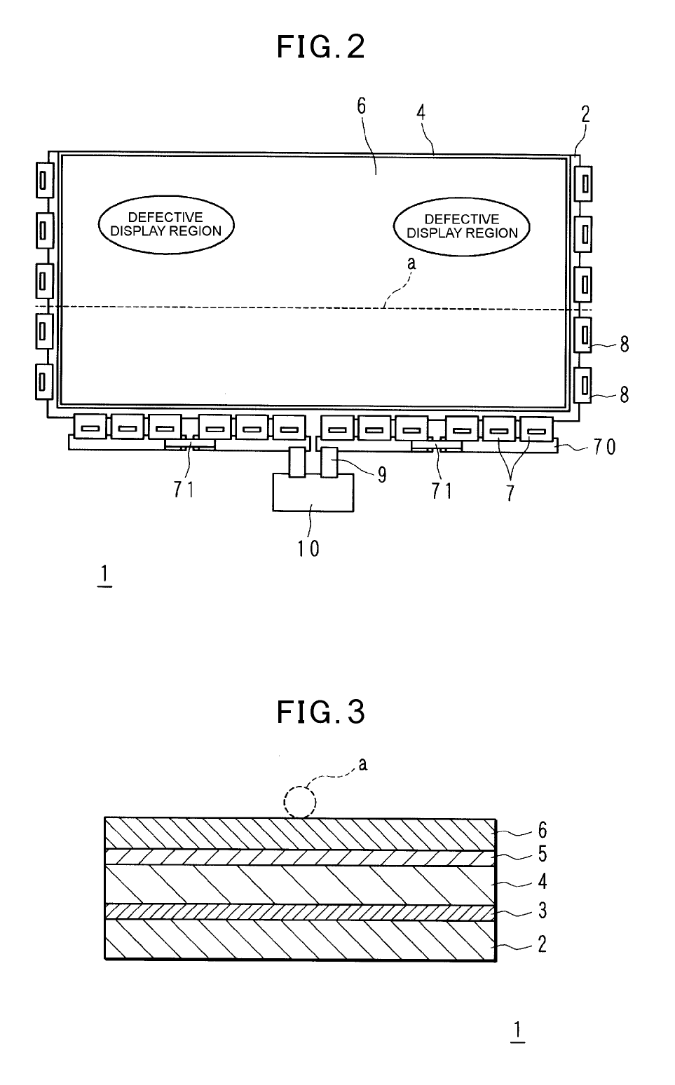

FIG. 1 shows an external perspective view of a liquid crystal display apparatus 100 for a television receiver according to Embodiment 1, FIG. 2 shows a schematic plan view of a display panel 1 of the liquid crystal display apparatus 100, and FIG. 3 shows a schematic cross-sectional view of the display panel 1 when viewing the display panel from a right side in FIG. 2. In FIG. 3, the components having configurations common to those in FIG. 11 are denoted by the same reference numerals. In the exemplary embodiments described below, a polarizing film adhered to the TFT substrate 2 is not shown, but it should be noted that the method for dividing a display member according to the present invention can be applied also to the TFT substrate 2 in the similar way that it is applied to the CF substrate 4.

A liquid crystal display apparatus 100 comprises a display module 11 including a display panel 1 and a back light unit (not shown), a front cabinet 12 and rear cabinet 13 that are both made of synthetic resin configured to accommodate the display module 11 so as to sandwich the display module 11, a tuner 14 with which to receive a broadcast wave from an antenna (not shown), a decoder 15 with which to decode a encoded broadcast wave, and a stand 16. The display module 11 has a horizontally long, substantially rectangular parallelepiped shape as a whole and is housed vertically between a front cabinet 12 and a rear cabinet 13.

As shown in FIG. 3, the display panel 1 includes a TFT substrate 2, a CF substrate 4, a liquid crystal layer 3 and a polarizing film 6. The TFT substrate 2 and the CF substrate 4 are bonded together with a liquid crystal layer 3 therebetween at the respective peripheral edges using a sealing material. The liquid crystal layer 3 is formed by injecting a vertical alignment type liquid crystal material between the TFT substrate 2 and the CF substrate 4. For a method for forming the liquid crystal layer 3, a liquid crystal drop fill method may be adopted such that a liquid crystal material is dispensed in a seal pattern frame of one of the two substrates before two substrates are bonded and then the other substrate is superimposed and bonded to the substrate under a reduced pressure.

The TFT substrate 2 includes an insulating substrate made of, for example, a glass, (not shown, same for the following components), onto which a TFT (thin film transistor) with a gate electrode, a source electrode and a drain electrode, a plurality of gate wirings (scanning wirings) to provide a scanning signal to the TFT, and a plurality of source wirings (signal wirings) to provide an image signal to the TFT are formed, and, a pixel electrode including, for example, ITO is formed on the surface of the TFT substrate 2.

In an exemplary embodiment shown in FIG. 2, a plurality of gate drivers 8 is arranged on both of the short sides of the TFT substrate 2. A pair of source substrates 70 is formed by connecting two of the source substrates 70, on each of which three source drivers 7 are mounted, via a connecting part 71, and two pairs of source substrates 70 are arranged on a long side of the TFT substrate 2. The each end, which is close to the center of the TFT substrate 2, of two of the source substrates 70 each positioned close to the center of the TFT substrate 2 among two pairs of source substrates 70 is connected to a control substrate 10 through FFCs (flexible flat cables) 9.

The CF substrate 4 includes an insulating substrate made of, for example, a glass, (not shown, same for the following components), onto which a black matrix (BM) and color filters such as R (red), G (green) and B (blue) are arranged, and, a common electrode including, for example, ITO is formed on the surface opposite to the liquid crystal layer 3.

The polarizing film 6 is formed by, for example, covering both surfaces of an optical film such as a PVA film with a protection film, and is adhered on a surface of the CF substrate 4, which is opposite to the surface facing the liquid crystal layer 3, using a curing type adhesive 5.

As mentioned above, a similar polarizing film can be disposed on a surface of the TFT substrate 2, which is opposite to the surface facing the liquid crystal layer 3, which is not shown in the drawing.

A back light unit is provided on the rear surface of the display panel 1. The back light unit may be either of edge-light type (side light type, light guiding plate type) and direct light type.

In each pixel of the display panel 1, a gate signal is sent from a gate driver 8 to the gate electrode through the gate wiring, and when the TFT is on state, a source signal is sent from a source driver 7 to the source electrode through the source wiring, and then an electric charge corresponding to the source signal is written in the pixel electrode through a semiconductor film and a drain electrode. This leads a generation of an electric potential difference between each of the pixel electrodes of the TFT substrate 2 and the common electrode of the CF substrate 4, and a voltage corresponding to the source signal is applied to the liquid crystal layer 3, namely, to a liquid crystal capacitance of each pixel and an auxiliary capacitance connected in parallel with the liquid crystal capacitance. In each pixel of the display panel 1, alignment state of the liquid crystal layer 3 will change depending on the magnitude of the voltage applied to the liquid crystal layer 3, and thus an image is displayed under a state where a transmittance of the liquid crystal layer 3 has been adjusted.

As shown in FIG. 2, there is a case where a defective display region is generated in a display region of the CF substrate 4 of the display panel 1. In this case, the display region is divided into a part to be remained (lower part from the dividing line “a” in FIG. 2) and a part to be reproduced (upper part from the dividing line “a” in FIG. 2) along the dividing line “a”, so that the part having a display region with good quality can be reused. In order to manufacture a reproduced article of the liquid crystal display apparatus having a display region with good quality, it will be necessary that the source driver 7 and the control substrate 10 are located within the display region where there is no defective region.

FIG. 3 shows a schematic cross-sectional view for describing an exemplary method for dividing the CF substrate 4 along the dividing line “a” in FIG. 2.

In the presently illustrated embodiment, the polarizing film 6 and the curing type adhesive 5 are cut along the dividing line “a”, and the CF substrate 4 is divided. Then the right side part in FIG. 3, which needs to be reproduced, (the part of CF substrate 4, curing type adhesive 5, polarizing film 6, and liquid crystal layer 3 which includes a defective display region) is removed leaving the TFT substrate 2 and is replaced by a reproduced part.

The following Table 1 shows steps of the method of dividing the display panel 1 according to the presently illustrated embodiment.

TABLE 1

| Process | Object to be processed | Device |
|---|---|---|
| (1) Cutting (dividing) | Polarizing film | Ultrasonic cutting |
| process | | roller |
| (2) Cutting process | Curing type adhesive | |
| (3) Scribing process for | CF substrate | |
| substrate (generation of | | |
| cracks) | | |
| (4) Applying sealing | on a dividing line | Dispenser |
| compound | | |
| (5) Substrate dividing | CF substrate | Substrate divider |
| process | | |
| (6) Curing process of | Ultraviolet treatment, | UV irradiator, |
| sealing compound | thermosetting treatment | thermosetting oven |
| | and the like | |

In the presently illustrated embodiment, the steps of Table 1, (1) cutting process for the polarizing film 6, (2) cutting process for the curing type adhesive 5, and (3) scribing process (scribing) for the CF substrate 4, are performed simultaneously using an ultrasonic cutting roller 30 described below.

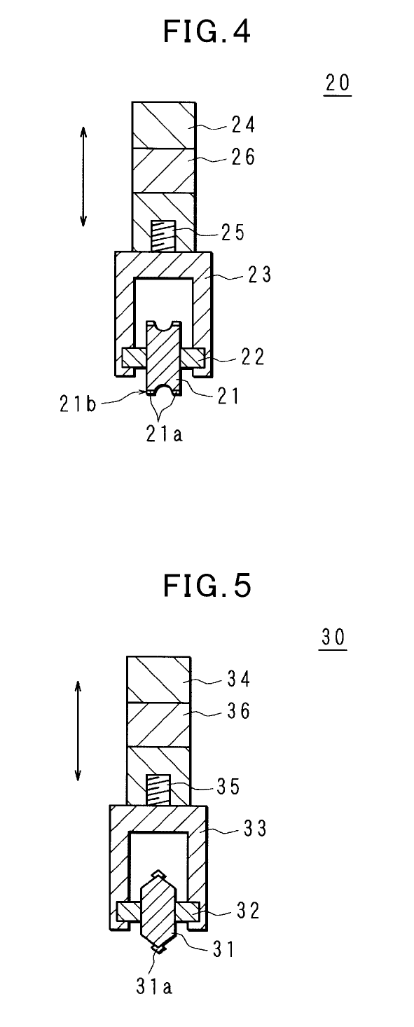

FIG. 4 and FIG. 5 show schematic cross-sectional views of ultrasonic cutting rollers 20 and 30, respectively.

The ultrasonic cutting roller 20 includes a cutting roller 21, a roller shaft 22, a roller bracket 23 and an oscillation part 24. The roller shaft 22 rotatably supports the cutting roller 21, and the roller bracket 23 supports both ends of the roller shaft 22 in such a way that the cutting roller 21 can rotate. The oscillation part 24 is configured to incorporate a piezoelectric element 26 and is mounted on the roller bracket 23 with a screw 25. The piezoelectric element 26 generates ultrasonic vibration, with which the ultrasonic cutting roller 20 is vibrated in a direction of an arrow in FIG. 4, which is, a direction vertical to the direction in which the roller bracket 23 holds the roller shaft 22.

Examples of the piezoelectric element 26 include, but not limited to, a piezoelectric element having 20 kHz frequency of vibrations of 50 μm in amplitude. This offers 20,000 times of vibrations of 50 μm in amplitude per second to the object, enabling to cut any materials, from a soft film made of synthetic resin to a hard glass by repeating a cycle of emitting a vibration energy toward the object with the small amplitude but with much impact and at high speed, and providing an excellent cutting efficiency.

A center part in the width direction of the outer circumferential surface of the cutting roller 21 is recessed and the cutting roller 21 includes a cutting portion 21b onto which cutter edges 21 are provided at both ends in the width direction of the outer circumferential surface of the cutting roller 21. This configuration enables a softly and easily removable polarizing film 6 to be discharged from a space between the cutter edges 21a. However, the configuration of the cutting portion 21b is not particularly limited to the above-described exemplary configuration, in which a recess at the center part in the width direction of the outer circumferential surface of the cutting roller 21 and cutter edges 21a and 21a are arranged contiguously. The recess and the cutter edges 21a and 21a can be arranged separatedly.

Both the curing type adhesive 5 and the CF substrate 4 are hard and broken easily. Since a part of curing type adhesive 5 is vitrified, it can be removed by causing a fracture at a contact part between the cutting roller and the curing type adhesive 5. Therefore, the ultrasonic cutting roller 30 shown in FIG. 5 may also be used.

The ultrasonic cutting roller 30 includes a cutting roller 31, a roller shaft 32, a roller bracket 33 and an oscillation part 34. The roller shaft 32 rotatably supports the cutting roller 31, and the roller bracket 33 supports both ends of the roller shaft 32 in such a way that the cutting roller 31 can rotate. The oscillation part 34 is configured to incorporate a piezoelectric element 36 and is mounted on the roller bracket 33 with a screw 35.

A center part in the width direction of the outer circumferential surface of the cutting roller 31 is protruded from the both ends in the width direction of the outer circumferential surface of the cutting roller 21. A plurality of cutter edges 31a can be provided contiguously at the center part in the width direction of the outer circumferential surface of the cutting roller 21, or a plurality of cutter edges 31a may be provided along the circumferential direction intermittently. A fracture of the curing type adhesive 5 can be caused with the center part in the width direction of the outer circumferential surface of the cutting roller 21.

Examples of the materials used for the cutter edges 21a, 31a of the ultrasonic cutting rollers 21, 31 include, but not limited to an ultrahard material, for example, the ones coated with, for example, titanium nitride (TiN), titanium carbonitride (TiCN), titanium aluminum nitride (TiAlN), aluminum chromium nitride (AlCrN), sintered material such as sintered diamond.

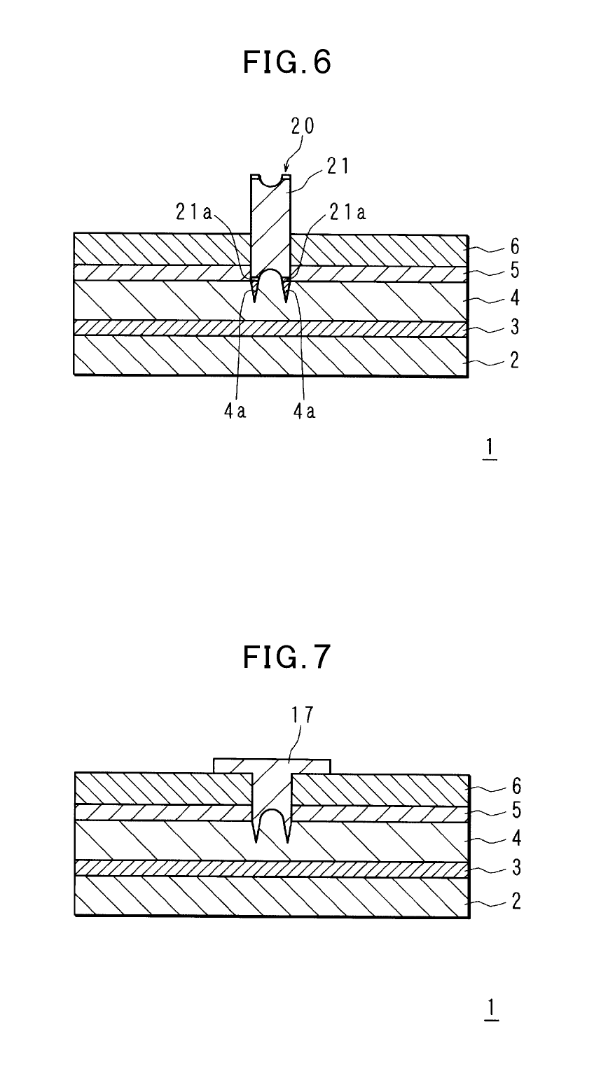

FIG. 6 shows a schematic cross-sectional view of the CF substrate 4 during the scribing process (process (3) in Table 1).

In the presently illustrated embodiment, in which a base substrate of the CF substrate 4 is glass, using an ultrasonic cutting roller 20 to the CF substrate 4 can cause cracks 4a easily at the contact parts with the cutting roller, as shown in FIG. 6.

FIG. 7 shows a schematic cross-sectional view of the CF substrate 4 to which a sealing compound 17 is applied at the cut parts of the polarizing film 6 and the adhesive 5 after subjecting the CF substrate 4 to scribing process (process (4) in Table 1).

Examples of the materials used for a sealing compound 17 includes, but not limited to, ultraviolet-curing resin and thermosetting resin, in particular, epoxy acrylate (brand name: “WORLD ROCK 700” manufactured by Kyoritsu Chemical & Co., Ltd.) and the like. The sealing compound 17 can be applied at a cut part using a dispenser.

As shown in FIG. 7, the applied sealing compound 17 can penetrate into cracks 4a of the CF substrate 4 utilizing capillary phenomenon.

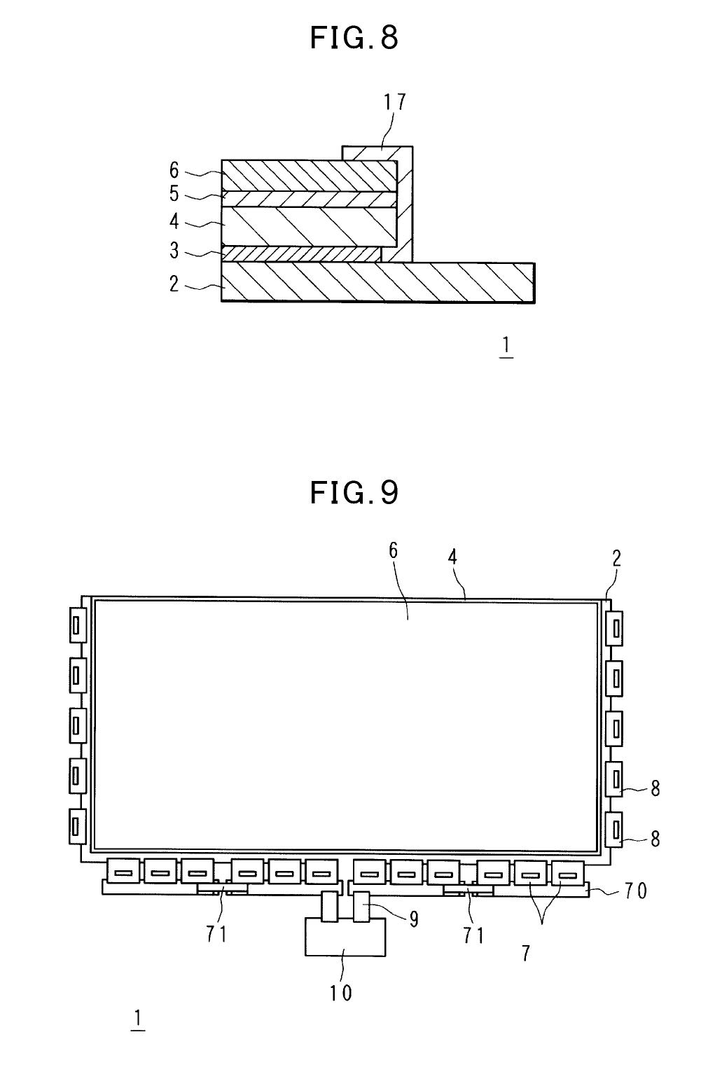

FIG. 8 shows a schematic cross-sectional view of the CF substrate 4 after being divided and a defective part was removed (process (5) in Table 1).

In the presently illustrated embodiment, after dividing the CF substrate 4, the sealing compound 17 can penetrate into a space generated between the CF substrate 4 and the TFT substrate 2 at the part where the CF substrate 4 was divided due to the difference between the pressure in that space and the atmospheric pressure outside the substrates. This can prevent an entering of air bubbles into the part where the CF substrate 4 was divided.

Next, the sealing compound 17 is cured (process (6) in Table 1).

When the sealing compound 17 is made of an ultraviolet-curing resin, ultraviolet rays are radiated to the sealing compound 17 by a UV irradiator to cure the sealing compound 17.

When the sealing compound 17 is made of thermosetting resin, a member to be treated is put into a thermosetting oven to heat and cure the sealing compound 17.

Then the liquid crystal layer 3, the CF substrate 4, the curing type adhesive 5 and the polarizing film 6 of the defective part are removed leaving the TFT substrate 2 to reproduce the display panel 1. In the presently illustrated embodiment a polarizing film adhered to the TFT substrate 2 is not shown, however, even when the polarizing film is adhered to the TFT substrate 2, the TFT substrate 2 can be divided in the similar way that it is described in the exemplary embodiment of the present invention.

FIG. 9 shows a schematic plan view of a reproduced display panel 1. In FIG. 9, the components same as those shown in FIG. 2 are denoted by the same reference numerals, for which detailed explanation will be omitted.

In the display panel 1 shown in FIG. 9, no defective parts are observed in the display region.

In the conventional method, it is difficult to divide the CF substrate 4 since the residue 51 from the curing type adhesive 5 is generated when removing the polarizing film 6, as shown in FIG. 12, due to the high adhesion between the curing type adhesive 5 and the substrate. However, in the presently illustrated embodiment of the present invention, the generation of the residue 51 is suppressed by using the ultrasonic cutting roller 20 or 30 and scribing process can be easily applied to the CF substrate 4, and this can simplify the dividing of the CF substrate 4.

Further, the sealing compound 17 is applied to the cut part before dividing the CF substrate 4, as described above, which can suppress the generation of air bubbles excellently during the dividing process.

### Embodiment 2

The following Table 2 shows steps of the method for dividing the display panel 1 according to Embodiment 2.

The method of dividing a display member according to Embodiment 2 has a configuration similar to that of the method of dividing a display member according to Embodiment 1 except that an ultrasonic cutter blade 40 is used in the process (2) in which the curing type adhesive 5 is cut.

TABLE 2

| Process | Object to be processed | Device |
|---|---|---|
| (1) Cutting (dividing) | Polarizing film | Ultrasonic cutting |
| process | | roller |
| (2) Cutting process | Curing type adhesive | Ultrasonic cutter |
| | | blade |
| (3) Scribing process for | CF substrate | Ultrasonic cutting |
| substrate (generation of | | roller |
| cracks) | | |
| (4) Applying sealing | on a dividing line | Dispenser |
| compound | | |
| (5) Substrate dividing | CF substrate | Substrate divider |
| process | | |
| (6) Curing process of | Ultraviolet treatment, | UV irradiator, |
| sealing compound | thermosetting treatment | thermosetting oven |
| | and the like | |

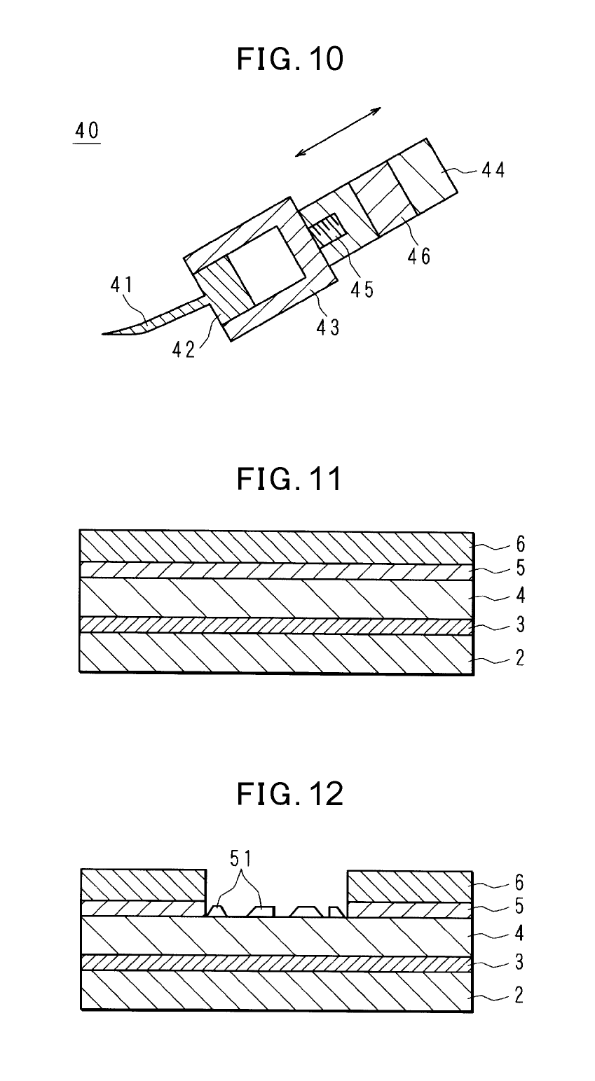

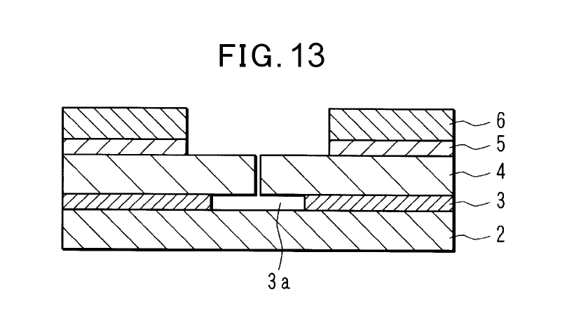

FIG. 10 shows a cross-sectional view of an ultrasonic cutter blade 40.

In the presently illustrated embodiment, the ultrasonic cutter blade 40 includes a blade part 41, a base 42, a blade bracket 43 and an oscillation part 44. The blade part 41 and the base 42 are arranged continuously, and the base 42 is held by the blade bracket 43. The oscillation part 44 is configured to incorporate a piezoelectric element 46 and is mounted on the blade bracket 43 with a screw 45. The piezoelectric element 46 generates ultrasonic vibration, with which the ultrasonic cutter blade 40 is vibrated in a direction of an arrow in FIG. 10, which is, a direction vertical to the direction in which the blade bracket 43 holds the base 42.

When the polarizing film 6 is cut along the dividing line “a” in FIG. 2 and removed and the residue 51 from the curing type adhesive 5 is generated as shown in FIG. 12, it will be necessary to remove the residue 51. A use of the ultrasonic cutter blade 40 enables a removal of the residue 51 to be generated. Preferably, the blade part 41 to be contacted with the CF substrate 4 has a flexibility, so that the residue 51 can be easily removed.

In the process (2) in which the curing type adhesive 5 is cut, the ultrasonic cutting roller 20 or 30 may be used first, and then the ultrasonic cutter blade 40 if the residue 51 is generated.

In the presently illustrated embodiment of the present invention, even if the residue is generated when cutting the adhesive, the residue can be removed, thereby the substrate will be divided easily.

### Embodiment 3

The following Table 3 shows steps of the method for dividing the display panel 1 according to Embodiment 3.

The method of dividing a display member according to Embodiment 3 has a configuration similar to that of the method of dividing a display member according to Embodiment 1 except that the process (3) in which the CF substrate 4 is scribed and the process (4) in which the sealing compound 17 is applied are performed under a reduced pressure.

TABLE 3

| Processing | Object to be processed | Device | Environment |
|---|---|---|---|
| (1) Cutting (dividing) | Polarizing film | Ultrasonic cutting roller | Atmospheric pressure |
| process | | | |
| (2) Cutting process | Curing type adhesive | Ultrasonic cutting roller | Atmospheric pressure |
| | | Ultrasonic cutter blade | |
| (3) Scribing process for | CF substrate | Ultrasonic cutting roller | Reduced pressure |
| substrate (generation of | | | |
| cracks) | | | |
| (4) Applying a sealing | on a dividing line | Dispenser | Reduced pressure |
| compound | | | |
| (5) Substrate dividing | CF substrate | Substrate divider | Atmospheric pressure |
| process | | | |
| (6) Curing process of | Ultraviolet treatment, | UV irradiator, | Atmospheric pressure |
| sealing compound | thermosetting treatment | thermosetting oven | |
| | and the like | | |

In the presently illustrated embodiment, since the scribing process of the CF substrate 4 is performed under a reduced pressure, the air does not enter into the cracks 4a of the CF substrate 4, preventing a generation of air bubbles. Further, the sealing compound penetrates into the cracks 4a when dividing the CF substrate which is put in the atmosphere after applying the sealing compound on the divided parts of the substrate under a reduced pressure. The sealing compound penetrates into the liquid crystal layer 3 arranged between the substrates using capillary phenomenon and an atmospheric pressure after the completion of the dividing, thereby preventing a generation of air bubbles when the substrate is the dividing.

It should be appreciated that the disclosed embodiments are intended to be illustrative and not restrictive in all respects. The scope of the present invention is not limited to the above-described context, and the meaning equivalent to the claims and all modifications within the scope of the claims are intended to be included. In addition, various embodiments obtainable by the combination of the technical means modified within the scope of the claim will be included in the technical scope of the present invention without contradiction.

For example, the substrate to be divided is not limited to the CF substrate 4. Further, the liquid crystal display apparatus according to the present invention is not limited to a television receiver. The method of dividing a display member may be applied to any of the display members other than the ones for liquid crystal display apparatus.

What is claimed is:

1. A method of dividing a display member comprising;
cutting a film and an adhesive of the display member using a cutting tool vibrated by ultrasonic waves on the display member, the display member comprising a pair of substrates bonded together at respective peripheral edges thereof and the film adhered to at least a first surface of the pair of substrates using the adhesive,
scribing the substrate exposed by cutting the film, and
dividing the substrate.

2. The method of claim 1, wherein the cutting tool is an ultrasonic cutting roller.

3. The method of claim 2, wherein a center part in the width direction of an outer circumferential surface of the ultrasonic cutting roller is recessed, and the ultrasonic cutting roller comprises a cutting portion, onto which cutter edges are provided at both ends in the width direction of the outer circumferential surface of the ultrasonic cutting roller.

4. The method of claim 1, wherein the adhesive is cut with an ultrasonic cutter blade.

5. The method of claim 1, wherein after scribing the substrate, a sealing compound is applied to a cut part of the film and a cut part of the adhesive, and the substrate is divided.

6. The method of claim 5, wherein the scribing of the substrate and an application of the sealing compound are performed under a reduced pressure, and
the substrate is divided.

7. The method of claim 1, wherein the film is an optical film.

8. A method of manufacturing a liquid crystal display apparatus, the method comprising manufacturing a display member by providing a liquid layer between two substrates, dividing the one substrate by the methods of claim 1, removing the one of divided parts of the substrate, and reproducing a part of the substrate corresponding a removed part.
